(19) United States
(12) Patent Application Publication
(10) Pub. No.: US 2025/0149463 A1
(43) Pub. Date: May 8, 2025

(54) TOP DIE BACK-SIDE MARKING FOR MEMORY SYSTEMS

(71) Applicant: Micron Technology, Inc., Boise, ID (US)

(72) Inventors: Po Chien Li, Taichung (TW); Yu Kai Kuo, Taichung (TW); Yi Wen Chen, Taichung (TW); Ming Wei Tsai, Taichung (TW); Chien Nan Fan, Taichung (TW); Chun Ming Huang, Taichung (TW); Angelo Oria Espina, Catarman (PH); Chun Jen Chang, Taichung (TW)

(21) Appl. No.: 18/929,394

(22) Filed: Oct. 28, 2024

Related U.S. Application Data
(60) Provisional application No. 63/547,316, filed on Nov. 3, 2023.

(51) Int. Cl. H01L 23/544; H01L 21/66; H01L 23/00; H01L 25/065; H10B 80/00

(52) U.S. Cl. CPC H01L 23/544; H01L 22/20; H01L 24/08; H01L 24/16; H01L 24/81; H01L 25/0657; H10B 80/00; H01L 2223/54426; H01L 2224/08146; H01L 2224/16148; H01L 2224/81095; H01L 2224/8113; H01L 2225/06541; H01L 2924/3511

(57) ABSTRACT

Methods, systems, and devices for top die back-side marking for memory systems are described. One or more alignment marks may be added to the back-side of a top memory die in a multi-layer memory device and used to align a position of the top memory die relative to a position of a memory die below the top memory die. The alignment marks may be formed on the top memory die during the manufacturing process of the multi-layer memory device. Operations for forming the alignment marks are described using various semiconductor fabrication techniques. Operations are also disclosed for using the alignment marks to modify placement of the top memory die to reduce the alignment offset in the manufacturing process of subsequent memory dies.

### CROSS REFERENCE

The present Application for Patent claims priority to and the benefit of U.S. Provisional Patent Application No. 63/547,316 by Li et al., entitled “TOP DIE BACK-SIDE MARKING FOR MEMORY SYSTEMS,” filed Nov. 3, 2023, assigned to the assignee hereof, and is expressly incorporated by reference in its entirety herein.

### TECHNICAL FIELD

The following relates to one or more systems for memory, including top die back-side marking for memory systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells. Some memory devices may include multiple layers of memory dies that include memory cells to store information. The memory device may be formed by stacking the memory dies together during a manufacturing process.

### BRIEF DESCRIPTION OF THE DRAWINGS

FIG. 1 shows an example of a system that supports top die back-side marking for memory systems in accordance with examples as disclosed herein.

FIG. 2 shows a side elevational view of a memory device that supports top die back-side marking for memory systems in accordance with examples as disclosed herein.

FIG. 3 shows a side elevational view of a system that supports top die back-side marking for memory systems in accordance with examples as disclosed herein.

FIG. 4 shows a side elevational view and a top plan view of a top memory die that supports top die back-side marking for memory systems in accordance with examples as disclosed herein.

FIG. 5 shows an example of steps in a manufacturing process that supports top die back-side marking for memory systems in accordance with examples as disclosed herein.

FIG. 6 shows an example of a manufacturing process that supports top die back-side marking for memory systems in accordance with examples as disclosed herein.

FIG. 7 shows a side elevational view of a memory device that supports top die back-side marking for memory systems in accordance with examples as disclosed herein.

FIGS. 8 through 11 show flowcharts illustrating a method or methods that support top die back-side marking for memory systems in accordance with examples as disclosed herein.

### DETAILED DESCRIPTION

Multi-layer memory devices may be formed by stacking individual memory dies on top of each other as part of the manufacturing process. The stacking process uses accurate alignment of the memory dies so that components such as through silicon vias (TSVs) couple with each other in different layers when the memory dies are bonded together. For example, various alignment techniques may be used to align the pillars of a first memory die with pads of a second memory die beneath the first memory die. Many memory dies include components that are detectable on both a first side (e.g., bottom) of the memory die and a second side (e.g., top) of the memory die. For example, if a memory die includes a TSV, it may be observable on both the first side and the second side. In a multi-layer memory device, however, a second side of the top memory die (e.g., the final memory die added to the stack of memory dies) may be blank (e.g., substantially free from markers present on the second side of other memory dies). Consequently, it may be challenging to align the top memory die with the stack of memory dies beneath such that pillars on a first side of the top memory die connect with the pads of the memory die immediately beneath. Misalignment of the top memory die may result in failure of the entire multi-layer memory device. Furthermore, such misalignment may reduce the yield of memory devices in the manufacturing process.

Techniques are described for adding one or more alignment marks to the second side of a top memory die in a stack of memory dies. The one or more alignment marks may be used to align a position of the top memory die relative to a position of a memory die below the top memory die. The one or more alignment marks may be formed on the top memory die during the manufacturing process. Operations for forming the one or more alignment marks are described using various semiconductor fabrication techniques (e.g., photolithography, etching, etc.). The multi-layer memory device may be inspected after the manufacturing process to identify any alignment offset associated with the top memory die. Operations are also disclosed for using the one or more alignment marks to modify placement of the top memory die as part of subsequent manufacturing operations to reduce or eliminate the alignment offset in the manufacturing process of subsequent memory dies. By reducing misalignment of the top memory die, the yield of memory devices in the manufacturing process may be increased.

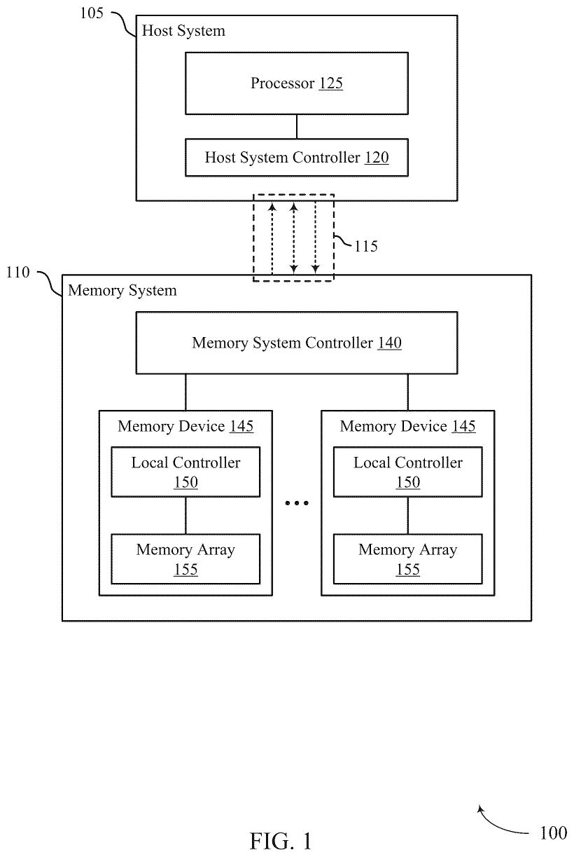

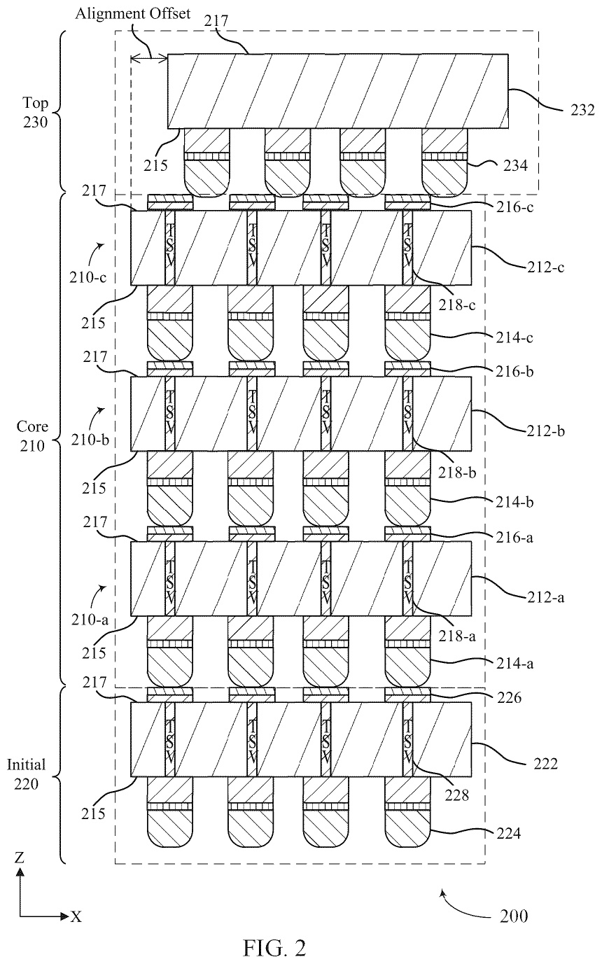

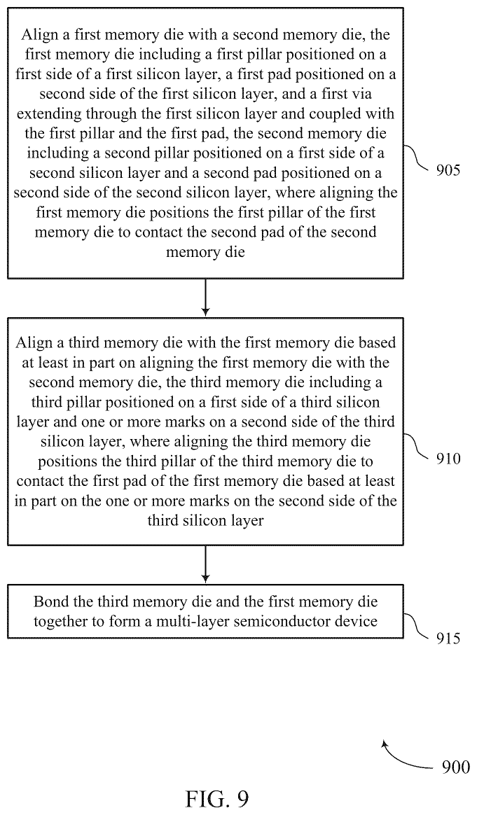

Features of the disclosure are illustrated and described in the context of systems and architectures with respect to FIG. 1. Features of the disclosure are further illustrated and described in the context of manufacturing processes that support top die back-side marking for memory systems with respect to FIGS. 2-8. These and other features of the disclosure are further illustrated by and described with reference to flowcharts that relate to manufacturing processes that support top die back-side marking for memory systems with respect to FIGS. 9-11.

FIG. 1 illustrates an example of a system 100 that supports top die back-side marking for memory systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not—or (NOR) memory cells, and not—and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

As described herein, a multi-layer semiconductor device may be formed by stacking multiple memory dies, such as memory array 155, on top of each other. For example, a first memory die may be aligned with, and positioned on, a second memory die such that a first pillar of the first memory die contacts a second pad of the second memory die. A third memory die may be aligned with, and positioned on, the first memory die such that a third pillar of the first memory die contacts a first pad of the first memory die. According to the described examples, the third memory die includes one or more marks on a second surface that faces away from the first memory die. The third memory die and the first memory die are then bonded together to form the multi-layer semiconductor device. In some examples, the multi-layer semiconductor device may be used as the memory devices 145 in the memory system 110.

In some examples, the one or more marks may be formed on the second surface of the third memory die prior to aligning with the first memory die using different fabrication processes. In some examples, a post-bonding inspection may be performed on the multi-layer semiconductor device to detect an alignment offset between the third memory die and the second memory die. The alignment offset may be used to adjust one or more alignment procedures during the manufacturing process for subsequent multi-layer semiconductor devices. The described processes may be used to improve alignment of the third memory die with the second memory die, thereby reducing the failure rate of multi-layer semiconductor devices produced from the manufacturing process. Additionally, the yield associated with the manufacturing process may be increased, thereby reducing costs.

In addition to applicability in systems as described herein, techniques for top die back-side marking for memory systems may be implemented to improve the sustainability of various electronic devices and systems. As the use of electronic devices has become increasingly widespread, the amount of energy used, and environmental implications associated with production of electronic devices and device operation has increased. Further, waste associated with disposal of electronic devices may also be detrimental for various reasons. Implementing the techniques described herein may reduce impacts related to electronic devices by improving alignment of individual layers in producing multi-layer semiconductor devices, which may reduce product failure rates during quality testing associated with the manufacturing processes, reduce materials used in production of electronic devices, improve the yield associated with manufacturing process to produce electronic devices, among other benefits.

FIG. 2 shows an example of a memory device 200 that supports top die back-side marking for memory systems in accordance with examples as disclosed herein. The memory device 200 may be an example of a multi-layer semiconductor device that includes one or more first memory dies 210 (e.g., core memory dies), a second memory die 220 (e.g., initial memory die), and a top memory die 230 (e.g., top memory die). Although three first memory dies 210-a, 210-b, 210-c are shown in FIG. 2, other examples may include more, or less, first memory dies 210 (e.g., 2, 4, 8, 16, etc.). The multi-layer semiconductor memory device may be an example of a high bandwidth memory (HBM) and the host system 105 may be configured to communicate with the memory device 200 using an HBM communication protocol, or another protocol defined by an industry standardized specification (e.g., a JEDEC specification).

A multi-layer semiconductor device may include two or more memory dies stacked on top of one another. Stacking memory dies may allow a memory system to increase the density of memory cells within the same footprint. Control circuitry for the two or more memory dies may be included in a substrate positioned below the stack of memory dies (e.g., CMOS-under-array). For example, a substrate may include supporting circuitry such as drivers, decoders, error control circuitry, and sense amplifiers (among other components). The second memory die 220 (e.g., initial memory die) may be positioned to contact the substrate. Other memory dies (such as one or more first memory dies 210 that are part of the core and the top memory die) may be stacked on top of the second memory die 220.

While features of the present disclosure are described in the context of memory dies (e.g., first memory dies 210, a second memory die 220, and a top memory die 230), these features may be applied to any stacked semiconductor device. For example, the memory device 200 may be an example of a multi-layer semiconductor device that includes one or more first dies (e.g., core dies), a second die 220 (e.g., initial die), and a top die 230 (e.g., top die). Although three first dies 210-a, 210-b, 210-c are shown in FIG. 2, other examples may include more, or less, first dies 210 (e.g., 2, 4, 8, 16, etc.). Any features, techniques, or relationships described with reference to the memory device 200 and/or memory dies may also apply to a more generic semiconductor device that includes stacked dies.

Some of the dies included in the stack of memory dies may include a silicon layer, pillars, and pads. For example, each of the first memory dies 210 may include a first silicon layer 212, one or more pillars 214 that are formed on a first side 215 of the first silicon layer 212 (e.g., first memory die 210), and one or more corresponding pads 216 that are formed on a second side 217 of the first silicon layer 212. In some examples, TSVs 218 may be formed in each first memory die 210 and coupled with each other in different first memory dies 210 (e.g., 210-a, 210-b, 210-c). The TSVs 218 may be configured to couple the pads 216 on the second side 217

The second memory die 220 may include a second silicon layer 222, one or more pillars 224 that are formed on a first side 215 of the second silicon layer 222 (e.g., second memory die 220), and one or more corresponding pads 226 formed on a second side 217 of the second silicon layer 222. One or more TSVs 228 may be formed in the second memory die 220. In some examples, the TSVs 228 in the second memory die 220 may be coupled with TSVs 218 formed in the first memory die 210. In some examples, the pillars 224 formed on the first side 215 of the second silicon layer 222 may be coupled with electronic circuitry (not shown) included in a substrate associated with the memory device 200. For example, the electronic circuitry may be formed on substrates for communicating with some or all the memory dies (e.g., first memory dies 210, second memory die 220, and top memory die 230).

The top memory die 230 may also include a third silicon layer 232 and one or more pillars 224 that are formed on a first side 215 thereof. In contrast to the first memory dies 210 and the second memory die 220, the top memory die 230 does not include pads on its second side 217 or TSVs. In some examples, the top memory die 230 may include TSVs (not shown) that only extend to a region below the top surface (e.g., second side 217). In other words, such TSVs may not extend through the second side 217 of the top memory die 230 in order to prevent electrical shorting that may cause failure in the memory device 200. For example, the top of the stacked memory device may be coupled with other components that may cause electrical challenges if TSVs are exposed in the top memory die 230. In some examples, the second side 217 of the top memory die 230 may not have any patterns or marks. Depending on the specific application of the memory device 200, heat sinks (not shown) may be coupled to the top memory die 230 after completing the manufacturing process.

The memory device 200 may be formed through a manufacturing process that aligns and stacks the different memory dies 210, 220, 230 together. In some examples, a manufacturing system (not shown) may align one of the first memory dies 210-a with the second memory die 220. For example, the manufacturing system may use information associated with the location of the pillars 214 and TSVs 218 of the first memory die 210-a and the pads 226 and TSVs 228 of the second memory die 220 to align the first memory die 210 with the second memory die 220. Additional first memory dies 210 may be aligned in a similar manner (e.g., first memory die 210-a and first memory die 210-b). The manufacturing system may also detect alignment marks (not shown) on the first side 215 (e.g., bottom) of the first silicon layer 212 and on the second side 217 (e.g., top) of the second silicon layer 222 during the alignment process. In some examples, a first temperature and pressure may be applied to cause an initial bonding between the first memory dies 210 and the second memory die 220. The first temperature and first pressure may be applied as part of a first type of bonding operation. In some examples, a second type of bonding operation may be performed on the memory device 200 after all of the memory dies are in the stack. The second type of bonding operation may apply a second temperature and a second pressure to the memory device 200 after aligning and stacking the top memory die 230. The second temperature and second pressure may be greater than the first temperature and first pressure applied to the first memory dies 210 and the second memory die 220. Additionally, the second temperature and second pressure may cause melting of electrical connectors to couple the first memory dies 210, the second memory die 220, and the top memory die 230, thereby enabling communication of signals (e.g., command, data, etc.) between different memory dies using the TSVs.

As illustrated in FIG. 2, the top memory die 230 does not include TSVs, or detectable patterns, on the second side 217. The lack of such features may cause difficulties in aligning the top memory die 230 with the first memory die 210-c. During the manufacturing process, for example, pillars 234 of the top memory die 230 may not be properly aligned with the pads 216 of the final first memory die 210-c. Misalignment of the top memory die 230 may result in a connection failure of the memory device 200. For example, the misalignment (e.g., shifting) of the top memory die 230 may result in an offset between the pillars 234 of the top memory die 230 and the pads 216 of the final first memory die 210-c. The offset may cause some pillars 234 to contact multiple pads 216 of the final first memory die 210-c, or fail to contact any pads 216 from the final first memory die 210-c. During a test or inspection procedure for the memory device 200, electrical shorting or interconnection failure between the top memory die 230 and the final first memory die 210-c may be detected as a result of such misalignment. Consequently, the memory device 200 would be discarded.

Numerous factors may further contribute to misalignment of the top memory die 230. For example, the manufacturing system may be used to transport and position the top memory die 230 on the first memory dies 210. In some instances, the position of the top memory die 230 may shift due to movement or miscalibration of the manufacturing system. In other instances, the position of the top memory die 230 may shift due vibration during transport. The manufacturing system may also include a vacuum chuck which secures the top memory die 230. Variations in the vacuum pressure may cause the top memory die 230 to shift during transport.

Misalignment of the top memory die 230 can occur in different ways. For example, the top memory die 230 may shift along a first axis (e.g., X-axis), as shown in FIG. 2. The top memory die 230 may also shift along a second axis (e.g., Y-axis) perpendicular to the side elevational plane shown in FIG. 2. The top memory die 230 may also experience rotational shifts (e.g., 0) along a plane defined by the first axis and the second axis (e.g., about the Z-axis). In some examples, misalignment of the top memory die 230 may be detected by measuring displacement along the first axis, displacement along the second axis, the rotational shift, or any combination thereof.

If left uncorrected, the amount of misalignment may continually change and even increase as additional memory devices 200 are produced during the manufacturing process. For example, misalignment associated a first memory device 200 resulting from a shift of 2μ along the first axis may continually increase to exceed 10μ for subsequent memory devices 200 as the manufacturing process progresses. The increased level of misalignment may result in test failures and adversely affect the yield of memory devices 200 produced in the manufacturing process.

According to examples described herein, one or more marks (e.g., alignment marks) may be formed on the second side 217 of the top memory die 230 in order to assist in aligning the top memory die 230 with the first memory dies 210. In some examples, the one or more marks may be located in positions on the second side 217 based on alignment marks on the first side 215 of the memory die or the location of pillars 234 formed on the first side 215 of the memory die. The one or more marks may be used by the manufacturing system to determine a position and orientation for the top memory die 230. For example, the one or more marks may be used to determine the center and rotation angle of the top memory die 230. Accordingly, the manufacturing system may reference the detectable patterns on the second side 217 of the first memory die 210, thereby improving the accuracy with which the manufacturing system may align the top memory die 230 with the first memory die 210.

In some examples, the memory device 200 may be subjected to a post-bonding inspection after performing the second type of bonding operation to apply the second temperature and the second pressure. The post-bonding inspection may utilize one or more inspection detectors (e.g., cameras) to identify an alignment offset between the top memory die 230 and the first memory dies 210. The alignment offset may be based on displacement along the X-axis, displacement along the Y-axis, rotation on the X-Y plane (e.g., about the Z-axis), or any combination thereof.

According to the examples described herein, the alignment offset may be used to improve processes associated with aligning the top memory die 230 with the first memory die 210. In some examples, a threshold may be associated with the alignment offset. The threshold may incorporate one or more components (or parameters) based at least in part on the information obtained from the one or more inspection cameras. For example, the threshold may be in the form of: Threshold (x, y, θ), where x=displacement along the X-axis, y=displacement along the Y-axis, and/or θ=rotation about the Z-axis-alone or in any combination.

For example, threshold (3,3,5) may be satisfied when a displacement of less than 3μ along the X-axis, a displacement of less than 3μ along the Y-axis, and a rotation of less than 5° about the Z-axis are detected. As described herein, some or all parameters may be applied. Therefore, certain threshold parameters may have a value of zero (e.g., Threshold (3,0,0)) to indicate that a single parameter (e.g., displacement along the X-axis) may apply to the alignment offset. In response to the threshold being satisfied, the manufacturing system may be controlled to adjust the alignment of the top memory die 230 during the manufacturing process of subsequent memory devices 200. For example, the manufacturing system may adjust the alignment of the top memory die 230 of next memory device along the X-axis in order to reduce or eliminate any misalignment with the first memory dies 210. In some instances, the manufacturing system may also be examined in order to detect any calibration errors or damage that may affect alignment of the top memory die 230.

In some instances, the post-bonding inspection may be performed on a group of memory devices 200. Examples of the post-bonding inspection may include processes that measure aspects of a stacked memory device and may include cutting or otherwise exposing portions of the stacked memory device to measurement. The alignment offset values associated with the different memory devices 200 may be analyzed to obtain average values that are representative of the group of memory devices 200. The alignment offset values may be used to determine when the threshold parameters have been satisfied. Therefore, the manufacturing system may be controlled to adjust the position of top memory dies 230 during the manufacturing process of subsequent memory devices 200. In some instances, the manufacturing system may be controlled to make incremental adjustments that are less than the threshold values until a new post-bonding inspection is performed and the results are analyzed. The manufacturing system may be controlled to make additional adjustments based on the result of the new post-bonding inspection. In some examples, the manufacturing system may be controlled to make adjustments corresponding to values of the alignment offset.

According to the disclosed examples, the one or more alignment marks formed on the second side 217 of the top memory die 230 may improve alignment with the first memory dies 210 in order to reduce connection failures when the memory device 200 is tested. Post-bonding inspection may also be performed to identify an alignment offset between the top memory die 230 and first memory dies 210. When the alignment offset satisfies a threshold, one or more alignment processes associated with the top memory die 230 may be adjusted to reduce connection failures in the manufacturing process of subsequent memory devices 200. Accordingly, the number of memory devices 200 that are discarded may be reduced. Furthermore, the production yield of memory devices may be increased.

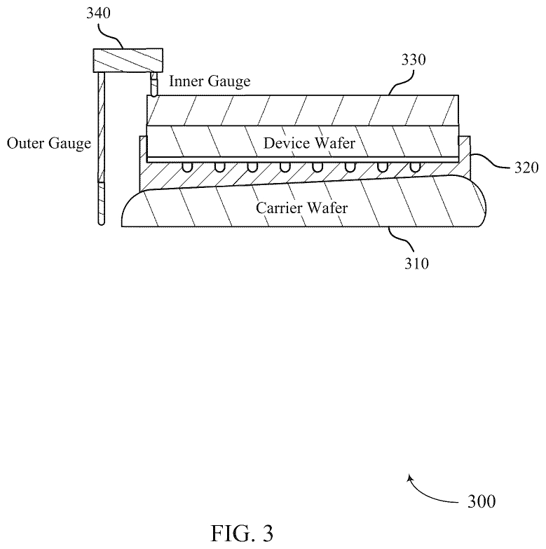

FIG. 3 shows an example of a system 300 that supports top die back-side marking for memory systems in accordance with examples as disclosed herein. In some examples, the system 300 may be used in a process to trim the top memory die 230 in order to achieve a desired parameters for the memory device 200. The parameters may be set in accordance with specific requirements or applications. For example, the memory device 200 may be used in an application that uses a specific height with low tolerances for variance from that specific height.

As part of manufacturing the top memory die 230, the memory die may be coupled with a carrier wafer 310. A carrier wafer may be an example of a substrate to which other semiconductor wafer may be bonded to during fabrication. By bonding a wafer with a carrier wafer, it may allow for safe handling and processing while preventing damage the wafer being manufactured. Accordingly, the processing for the top memory die 230 may include a process to trim the height of the top memory die 230, while also compensating for variations in the height of the first memory dies 210 and second memory die 220. The resulting memory device 200 would therefore satisfy the desired application height. In some examples, the top memory die 230 may be fabricated with a thickness that is greater than the thickness of each first memory die 210 or the thickness of the second memory die 220. Additionally or alternatively, the top memory die 230 may be bonded with the carrier wafer 310 as part of the process for forming the marks on the second side 217 of the top memory die 230.

According to the described examples, the system 300 may include a carrier wafer 310 on which a device wafer 330 (e.g., the top memory die 230) is mounted. The device wafer 330 may be an example of the top memory die 230. An adhesive such as a bonding glue 320 may be applied between the device wafer 330 and the carrier wafer 310. In some examples, the bonding glue 320 and carrier wafer 310 may be selected to reduce warpage of the device wafer 330. A bonding temperature may be applied to activate the bonding glue 320 and secure the device wafer 330. The device wafer 330 may be processed to a reduced height which satisfies the requirements for the memory device height.

The system 300 may include a measuring device 340 for measuring and monitoring the height (or thickness) of the device wafer 330 during the trimming process. In some examples, the measuring device 340 may include an inner gauge for physically detecting the height of the device wafer 330 and an outer gauge that measures the height of the carrier wafer 310. Once the device wafer 330 has reached the specified height, a debonding temperature may be applied to melt the bonding glue 320 and remove the device wafer 330 from the carrier wafer 310. While a measuring device 340 is shown for illustrative purposes, other measurement techniques may be used to measure the device wafer 330 (e.g., a touch-type measurement device or an optical-type measurement device).

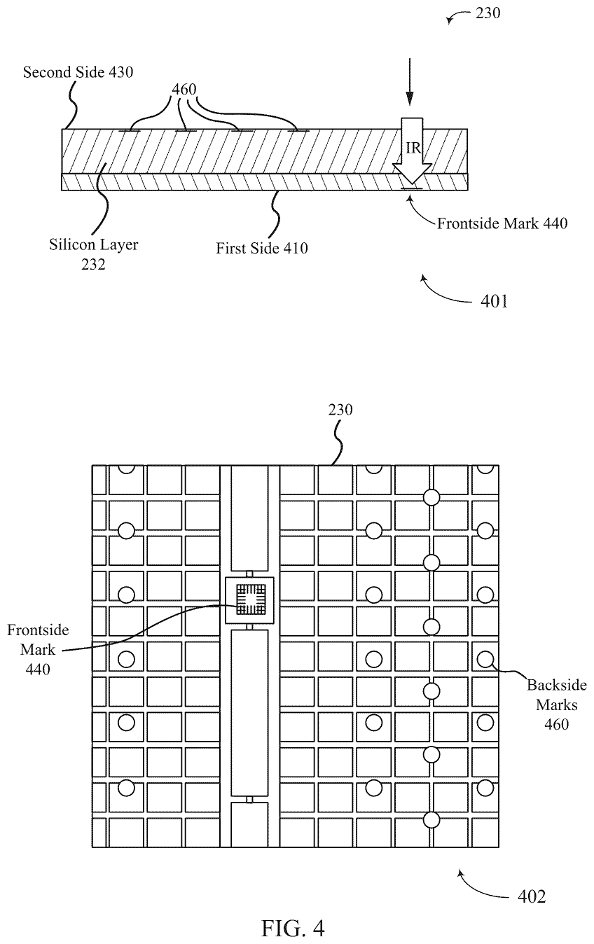

FIG. 4 shows a side elevational view of a top memory die 401 and a top plan view of the top memory die 402 that supports top die back-side marking for memory systems in accordance with examples as disclosed herein. The top plan view of the top memory die 402 illustrates a selective transparency to show features on a top surface (e.g., alignment marks on the back side) and other features that would the buried beneath the top surface (e.g., bottom-side mark or front-side). In some case, the first side 215 and/or the first side 410 may be referred to as a bottom-side or a front-side. In some cases, the second side 217 and/or the second side 430 may be referred to as a top-side or a back-side. Various processes may be performed to select the location of marks 460 (e.g., alignment marks) and form the marks 460 on the second side of the top memory die 230. According to the described example, the top memory die 230 may include a first side 410 that includes one or more pillars 234. The top memory die 230 may also include a silicon layer 232 (e.g., third silicon layer) and a second side 430 (e.g., top-side). In some cases, the second side 430 may be blank and may not include any structures that may be used in an alignment process. Techniques are described for forming the alignment marks 460 on the second side 430.

According to the examples described herein, a through silicon alignment (TSA) process may be performed on the top memory die 230 in order to detect the location of a front-side alignment mark 440 formed as part of the first side 410. The TSA process may be performed, for example, using one or more lithography tools. According to an example, an infrared (IR) beam may be directed toward the first side 410 of the top memory die 230. The IR beam may pass through the third silicon layer 232 to detect patterns and features formed in the first side 410. For example, the IR beam may be used to detect the location of a front-side alignment mark 440 formed as part of the first side 410. In some examples, the IR beam may be directed from an exposure tool (not shown) used in lithography processes. Once the IR beam identifies the location of the front-side alignment mark 440 from the first side 410, one or more locations for the marks 460 may be selected on the second side 430 of the top memory die 230.

The location identified based on detecting the front-side alignment mark 440 may be used to form a mark 460 (e.g., back-side alignment mark) on the second side 430 of the top memory die 230, in accordance with the described examples. As shown in FIG. 4, the mark 460 formed on the second side 430 of the top memory die 230 is positioned at a different location relative to the front-side alignment mark 440. As further shown in FIG. 4, one or more additional marks 460 may be formed on the second side 430 of the top memory die 230. The pattern of marks 460 on the second side 430 may include one mark or two or more marks in a pattern, depending on the location for the second marks may be based on the location of the front-side alignment mark 440, the location 450 of the mark 460, or both. According to the described examples, all the marks 460 formed on the second side 430 of the top memory die 230 are positioned at different locations relative to the front-side alignment mark 440.

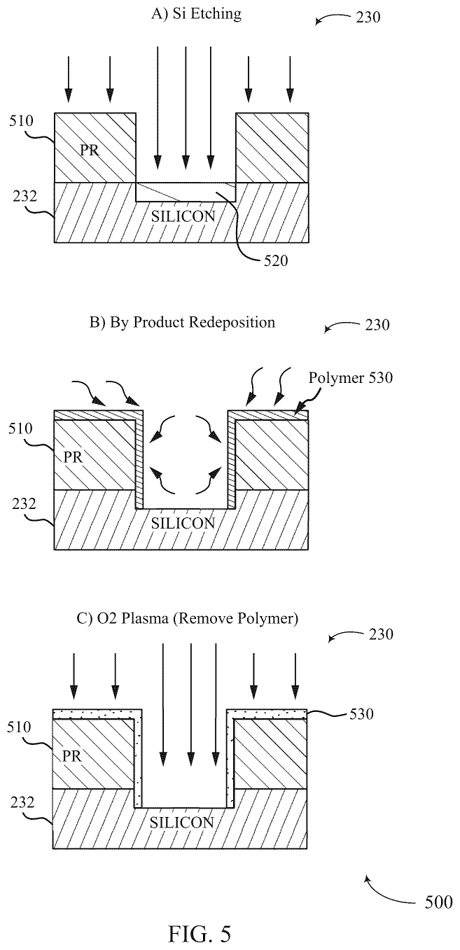

FIG. 5 shows an example of steps in a manufacturing process 500 that supports top die back-side marking for memory systems in accordance with examples as disclosed herein. According to the described examples, the second surface of the top memory die 230 may be processed to form a mark at the one or more locations identified during the TSA process. In some examples, multiple locations may be identified, thereby resulting in formation of multiple marks on the second side of the top memory die 230. As shown in FIG. 5, an etching process is performed on the second side of the top memory die 230. Although not shown, a layer of photoresist material 510 is first applied to the second side of the top memory die 210. In some examples, the photoresist material 510 may be applied using a spin-coating operation to achieve an even layer of material. A pattern corresponding to the mark 460 on the second side may be created in the photoresist material 510 using a development process that may involve exposing the photoresist material 510 to radiation. In some examples, a photomask may be used to define the mark by delineating where the radiation exposes the photoresist material 510. In some examples, the photomask may be used to define multiple marks on the photoresist material 510. According to the described examples, the one or more marks defined by the photomask may correspond to alignment marks e.g., (marks 460) on the second side of the top memory die 230.

Exposed photoresist areas may then be removed, for example, using an etch process to leave behind a desired pattern 520 within the third silicon layer 232. In some instances, the etch process may be a dry etch process. The etch process may remove the photoresist material 510 and at least a portion of the third silicon layer 232. In some examples, the dry etch process may generate byproducts (e.g., a polymer) that may form on the photoresist material 510 and/or the third silicon layer 232. The byproducts may be in the form a polymer layer 530 as shown in FIG. 5. The polymer layer 530, however, may prevent or reduce subsequent removal of the photoresist material 510. Accordingly, removal of the polymer layer 530 may be useful prior to removing the photoresist material 510 in order to prevent or reduce uniformity issues. In some examples, a plasma etch process may be performed to remove the polymer layer 530. In some instances, the plasma etch process may be a reactive ion etching (RIE) process utilizing oxygen gas. Once the polymer layer 530 has been removed, the photoresist material 510 may be removed from the second side of the top memory die 230. In some examples, a wet strip process may be performed to remove the photoresist material 510. The marks 460 may remain in the third silicon layer 232 because at least a portion of the third silicon layer was etched.

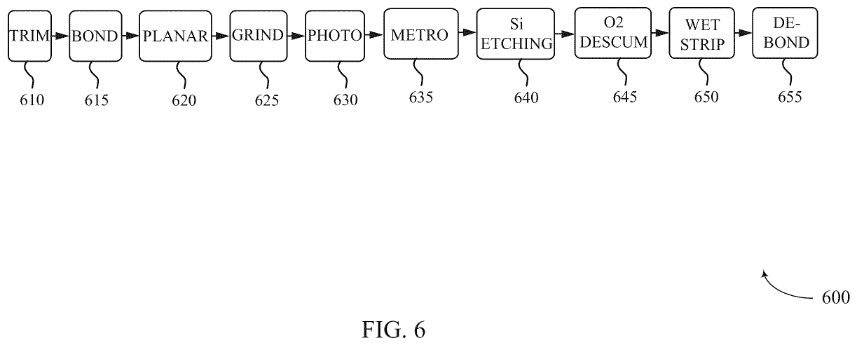

FIG. 6 shows an example of a manufacturing process 600 that supports top die back-side marking for memory systems in accordance with examples as disclosed herein. As shown in FIG. 6, the process begins after processing for the top memory die is complete and the top memory die is formed. At 610, the process may include performing a trimming operation to trim the top memory die 230.

At 615, the process may include reversibly bonding the first side of the top memory die 230 with a carrier wafer to perform additional processing steps without subjecting the top memory die 230 to unintended damage. In some cases, the carrier wafer may correspond to the carrier wafer 310.

At 620 and 625, the process may include a planarization operation and/or a grinding operation to reduce the thickness of the top memory die 230. In some examples, the thickness of the top memory die 230 may be continually monitored during the planarization operation and/or the grinding operation until a desired threshold is achieved. The planarization operation and/or the grinding operation may be performed in order to achieve a desired height for the memory device 200. In some examples, the planarization operation and/or the grinding operation performed at 620 and 625 may correspond to the operations described with reference to FIG. 3. In some cases, the planarization procedure and grinding procedure may also flatten and smoothen the second side of the top memory die 230. In some examples, the planarization process may include chemical mechanical polishing which applies a slurry fluid to the second side of the top memory die using a polishing tool. At 625, the process may include a grinding operation to further control the thickness of the top memory die 230.

At 630, the process may include applying a photoresist material to the second side of the top memory die 230. In some examples, the photoresist material may be applied using a spin coating operation. The photoresist material may also correspond to the photoresist material 510 shown in FIG. 5. The photoresist material may be developed at least in part using a reticle to define patterns for the one or more alignment marks on the second side of the top memory die 230.

At 635, process may include a metrology process to locate a reference point (e.g., a front-side mark) and select positions for one or more marks to put on a back-side of a top memory die 230. For example, measurement techniques may be used to identify a location of a front-side mark or other reference point. The manufacturing system may then identify locations for a pattern of marks on the back-side of the top memory die 230. In some examples, the metrology operation performed at 635 may correspond to the operations described with reference to FIG. 4. At 640, the process may include etching the photoresist material and silicon layer at the second side of the top memory die 230 to define the alignment marks. In some instances, the etching process may be a dry etch process, as described in more detail with reference to FIG. 5. At 645, the process may include performing a plasma etch process such as RIE utilizing oxygen gas to remove polymer redeposition resulting from etching the photoresist material. In some examples, the etching and RIE may correspond to the processes described with reference to FIG. 5.

At 650, the process may include stripping the photoresist material from the second side of the top memory die 230. In some examples a wet strip operation may be used to remove the photoresist material, as described in more detail with reference to FIG. 5. At 655, the process may include debonding the top memory die 230 from the carrier wafer. In some examples, the manufacturing system may utilize the alignment marks formed on the second side of the top memory die 230 to align the top memory die 230 with the first memory dies 210 in order to complete the memory device 200.

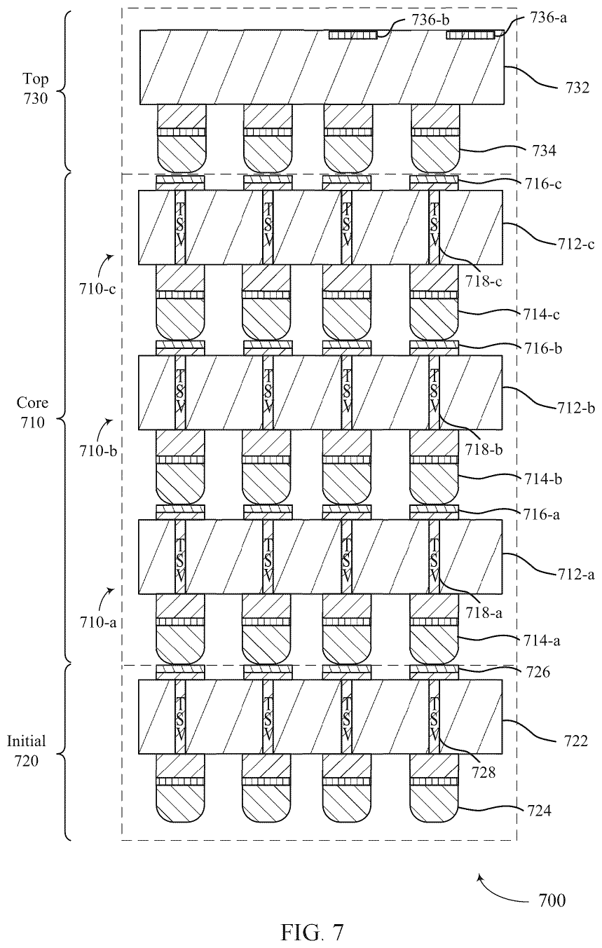

FIG. 7 shows an example of a memory device 700 that supports top die back-side marking for memory systems in accordance with examples as disclosed herein. In some examples, the memory device 700 may correspond to a second or subsequent memory device 700 manufactured after detecting an alignment offset. The memory device 700 may include one or more first memory dies 710 (e.g., core memory dies 710-a, 710-b, 710-c), a second memory die 720 (e.g., initial memory die), and a top memory die 730 (e.g., third memory die). In some examples, the memory device 700 may include more, or less, first memory dies 710 (e.g., 2, 4, 8, 16, etc.). A selected first memory die 710-a may be aligned with the second memory die 720. Two additional first memory dies 710-b, 710-c may also be stacked on the selected first memory die 710-a. In some examples, additional memory dies (not shown) may also be stacked on the selected first memory die 710-a. Each of the first memory dies 710 may include a first silicon layer 712, one or more first pillars 714 formed on a first side of the first silicon layer 712, and one or more corresponding first pads 716 formed on a second side of the first silicon layer 712. In some examples, one or more first TSVs 718 may be formed in each first silicon layer 712 and coupled with each other in different first memory dies 710 (e.g., 710-a, 710-b, 710-c).

The second memory die 720 may include a second silicon layer 722, one or more second pillars 724 formed on a first side of the second silicon layer 722, and one or more corresponding second pads 726 formed on a second side of the second silicon layer 722. One or more second TSVs 728 may be formed in the second silicon layer 722. In some examples, the second TSVs 728 in the second silicon layer 722 may be coupled with first TSVs 718 formed in the first silicon layer 712. In some examples, the second pillars 724 formed on the first side of the second silicon layer 722 may be coupled with electronic circuitry (not shown) associated with the memory device 700. For example, the electronic circuitry may be formed on substrates for communicating with some or all of the memory dies (e.g., first memory dies 710, second memory die 720, and top memory die 730).

The top memory die 730 may also include a third silicon layer 732, one or more third pillars 734 formed on a first side thereof. In contrast to the first memory dies 710 and the second memory die 720, the top memory die 730 does not include pads or TSVs on the second side of the third silicon layer 732. In some examples, the top memory die 730 may include TSVs (not shown) which only extend into a portion of the third silicon layer 732. In other words, such TSVs do not extend through the second side of the third silicon layer 732, thereby preventing electrical shorting that may cause failure in the memory device 700. In some examples, heat sinks (not shown) may be coupled to the top memory die 730 after the manufacturing process is completed.

The memory device 700 may be formed through a manufacturing process which uses a manufacturing system (not shown) to align one of the first memory dies 710-a with the second memory die 720. For example, the manufacturing system may align the first memory die 710-a with the second memory die 720 such that first pillars 714-a contact the second pads 726. In some examples, the manufacturing system may align additional first memory dies (e.g., 710-b, 710-c, etc.) in a similar. The manufacturing system may also detect alignment marks (not shown) on the first silicon layer 712 and the second silicon layer 722 during the alignment process. In some examples, a first type of bonding operation may be performed, using a first temperature and a first pressure, to cause an initial bonding between the first memory dies 710 and the second memory die 720.

According to the disclosed examples, the top memory die 730 may include one or more alignment marks 736-a, 736-b formed on the second side of the third silicon layer 732. In some examples, alignment marks 736-a and 736-b may correspond, respectively, to the one or more marks 460 shown in FIG. 4. The alignment marks 736 may be formed in accordance with the techniques described with respect to FIGS. 3-6. In some examples, the manufacturing system may use the alignment marks 736 to align the top memory die 730 with the first memory die 710 such that the third pillars 734 contact the first pads 716. A second type of bonding operation may be performed to couple the first memory dies 710, the second memory die 720, and the third memory die 730 together. In some examples, the second type of bonding operation may apply a second temperature and a second pressure to melt electrical connectors in the memory device 700, thereby enabling communication of signals (e.g., command, data, power, etc.) between the first memory dies 710, the second memory die 720, and the top memory die 730.

According to the example shown in FIG. 7, information obtained from an alignment offset associated with a previous memory device (e.g., memory device 200) is used to reduce or eliminate an alignment offset in the memory device 700. As previously discussed, one or more inspection cameras may be used to perform a post-bonding inspection after completing the manufacturing process. The post-bonding inspection may determine an alignment offset between the third memory die 230 and the first memory die 210 as shown in FIG. 2. The alignment offset may be based on displacement along the X-axis, displacement along the Y-axis, rotation about the Z-axis, or any combination thereof. The alignment offset may be used to determine when a threshold has been satisfied. Accordingly, one or more alignment procedures for the top memory die 730 are adjusted to reduce or eliminate the alignment offset. For example, the position of the top memory die 730 in the memory device 700 may be shifted and/or rotated to correct the alignment offset. According to the disclosed examples, misalignment of the third memory die may be reduced, thereby reducing the failure rate of memory devices during testing. Furthermore, the production yield of the memory devices may be increased.

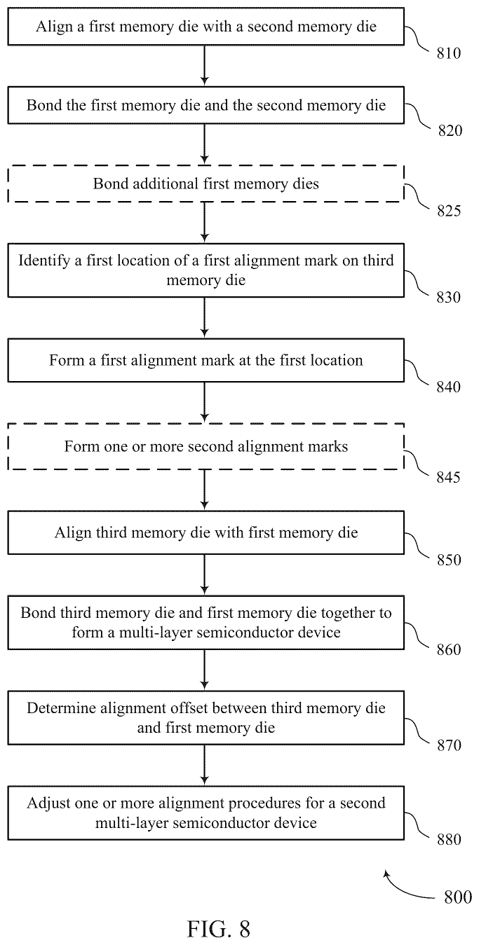

FIG. 8 shows a flowchart illustrating a method or methods 800 that support top die back-side marking for memory systems in accordance with examples as disclosed herein. The operations of method 800 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 810, the method may include aligning a first memory die with a second memory die. The first memory die may include a first silicon layer, a first pillar positioned on a first side of the first silicon layer, and a first pad positioned on a second side of the first silicon layer. The first memory die may also include a first via extending through the first silicon layer and coupled with the first pillar and the first pad. The second memory die may include a second silicon layer, a second pillar positioned on a first side of the second silicon layer, and a second pad positioned on a second side of the second silicon layer. In some examples, aligning the first memory die with the second memory die may include positioning the first pillar of the first memory die in contact with the second pad of the second memory die. In some examples, the second memory die may include a second via extending through the second silicon layer and coupled with the second pillar and the second pad. In some instances, the first memory die and the second memory die may correspond to the first memory dies 710 and second memory die 720 shown in FIG. 7.

At 820, the method may include bonding the first memory die and the second memory die. In some examples, the first memory die and the second memory die may be bonded together using a first type of bonding operation which applies a first pressure and a first temperature. At 825, the method may optionally include bonding additional first memory dies together. In some examples, the additional first memory dies may correspond to first memory die 710-b and 710-c shown in FIG. 7. In some examples, the additional first memory dies may be bonded together during the first type of bonding operation.

At 830, the method may include identifying a first location of a first alignment mark on a third memory die. In some examples, the third memory die may include a third silicon layer and a third pillar positioned on a first side of a third silicon layer. The first location of the first alignment mark may be identified on a second side of the third silicon layer. In some examples, a TSA process may be performed to detect the location of an alignment mark on the first side of the third silicon layer. The detected location may then be used to identify the first location of the first alignment mark on the second side of the third silicon layer.

At 840, the method may include forming one or more alignment marks at the first location on the second side of the third silicon layer. In some examples, the first alignment mark may be formed using various semiconductor fabrication techniques, such as those described with respect to FIGS. 5 and 6. For example, a layer of photoresist material may be applied on the second side of the third silicon layer. An etching process may be performed to remove portions of the photoresist material and the third silicon layer, thereby forming patterns which define the first alignment mark. The remaining layer of photoresist material may then be removed from the second side of the third silicon layer. In some examples, a dry etch process may be performed to remove portions of the photoresist material and the third silicon layer. In some examples, a wet strip process may be performed to remove the remaining layer of photoresist material from the second side of the third silicon layer.

At 845, the method may optionally include forming one or more second alignment marks at additional locations on the second side of the third silicon layer. In some examples, the first location of the first alignment mark may be used to identify locations for forming the second alignment marks. In other examples, additional TSA processes may be performed to detect locations of different alignment marks on the first side of the third silicon layer. The detected additional locations may then be used to identify locations at which the second alignment marks may be formed on the second side of the third silicon layer. In some cases, the forming of the alignment marks at 840 and 845 may be done before 810, or before 820, or before 825, or before 830.

At 850, the method may include aligning the third memory die with the first memory die (e.g., one or more first memory dies bonded with the second memory die). For example, the third pillar of the third memory die may be positioned to contact the first pad of the first memory die. In some examples, the alignment marks (e.g., the first alignment mark and/or the one or more second alignment marks) formed on the second side of the third silicon layer may be used to position the third memory die while aligning with the first memory die.

At 860, the method may include bonding the third memory die and the first memory die together to form a multi-layer semiconductor device. In some examples, a second type of bonding operation may be used to bond the third memory die and the first memory die together. The second type of bonding operation may apply a second pressure and a second temperature that are different from the first temperature and pressure applied during the first type of bonding application. In some examples, the second pressure and the second temperature may be higher than the first temperature and pressure and bonding the third memory die and the first memory die together may establish connections between the first memory die, the second memory die, and the third memory die.

At 870, the method may include determining an alignment offset between the third memory die and the first memory die. In some examples, a post-bonding inspection may be performed after bonding the third memory die and the first memory die in order to determine the alignment offset between the third memory die 230 and first memory die 210 shown in FIG. 2. The alignment offset may, for example, be based on displacement along the X-axis, displacement along the Y-axis, rotation on the X-Y plane (e.g., about the Z-axis), or any combination thereof. In some examples, the displacements and rotation may be determined using one or more inspection cameras during the post-bonding inspection.

At 880, the method may include adjusting one or more alignment procedures for a second (or next) multi-layer semiconductor being manufactured. The alignment procedures may be adjusted, for example, when the alignment offset satisfies a threshold. In some examples, the threshold may include parameters corresponding to displacement along the X-axis, displacement along the Y-axis, rotation on the X-Y plane (e.g., about the Z-axis), or any combination thereof. The second multi-layer semiconductor device may include one or more fourth memory dies aligned with a fifth memory die. In some examples, values associated with the alignment offset may be used to adjust placement of a sixth memory die on the fourth memory die when the alignment offset satisfies the threshold. In some examples, the sixth memory die may correspond to the top memory die 730 shown in FIG. 7. Therefore, the sixth memory die may include alignment marks (e.g., the one or more alignment marks 736-a and 736-b) formed on a second side of sixth silicon layer. Accordingly, the alignment marks may be used to adjust the positioning of the sixth memory die.

FIG. 9 shows a flowchart illustrating a method 900 that supports top die back-side marking for memory systems in accordance with examples as disclosed herein. The operations of method 900 may be implemented by a manufacturing system or one or more controllers or its components as described herein. For example, the operations of method 900 may be performed by a manufacturing system or one or more controllers as described with reference to FIGS. 1 through 8. In some examples, a one or more controllers may execute a set of instructions to control the functional elements of the manufacturing system to perform the described functions. Additionally, or alternatively, the manufacturing system or one or more controllers may perform aspects of the described functions using special-purpose hardware.

At 905, the method may include aligning a first memory die with a second memory die, the first memory die including a first pillar positioned on a first side of a first silicon layer, a first pad positioned on a second side of the first silicon layer, and a first via extending through the first silicon layer and coupled with the first pillar and the first pad, the second memory die including a second pillar positioned on a first side of a second silicon layer and a second pad positioned on a second side of the second silicon layer, where aligning the first memory die positions the first pillar of the first memory die to contact the second pad of the second memory die.

At 910, the method may include aligning a third memory die with the first memory die based at least in part on aligning the first memory die with the second memory die, the third memory die including a third pillar positioned on a first side of a third silicon layer and one or more marks on a second side of the third silicon layer, where aligning the third memory die positions the third pillar of the third memory die to contact the first pad of the first memory die based at least in part on the one or more marks on the second side of the third silicon layer.

At 915, the method may include bonding the third memory die and the first memory die together to form a multi-layer semiconductor device.

In some examples, an apparatus as described herein may perform a method or methods, such as the method 900. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for aligning a first memory die with a second memory die, the first memory die including a first pillar positioned on a first side of a first silicon layer, a first pad positioned on a second side of the first silicon layer, and a first via extending through the first silicon layer and coupled with the first pillar and the first pad, the second memory die including a second pillar positioned on a first side of a second silicon layer and a second pad positioned on a second side of the second silicon layer, where aligning the first memory die positions the first pillar of the first memory die to contact the second pad of the second memory die; aligning a third memory die with the first memory die based at least in part on aligning the first memory die with the second memory die, the third memory die including a third pillar positioned on a first side of a third silicon layer and one or more marks on a second side of the third silicon layer, where aligning the third memory die positions the third pillar of the third memory die to contact the first pad of the first memory die based at least in part on the one or more marks on the second side of the third silicon layer; and bonding the third memory die and the first memory die together to form a multi-layer semiconductor device.
Aspect 2: The method, apparatus, or non-transitory computer-readable medium of aspect 1, further including operations, features, circuitry, logic, means, or instructions, or any combination thereof for bonding the first memory die and the second memory die based at least in part on aligning the first memory die with the second memory die, where aligning the third memory die with the first memory die is based at least in part on bonding the first memory die and the second memory die.
Aspect 3: The method, apparatus, or non-transitory computer-readable medium of aspect 2, where bonding the first memory die and the second memory die together uses a first type of bonding operation including a first pressure and a first temperature and bonding the third memory die and the first memory die together uses a second type of bonding operation including a second pressure and a second temperature.
Aspect 4: The method, apparatus, or non-transitory computer-readable medium of any of aspects 1 through 3, further including operations, features, circuitry, logic, means, or instructions, or any combination thereof for determining an alignment offset between the third memory die and the first memory die based at least in part on the one or more marks and adjusting one or more alignment procedures for a second multi-layer semiconductor device based at least in part on the alignment offset.
Aspect 5: The method, apparatus, or non-transitory computer-readable medium of aspect 4, further including operations, features, circuitry, logic, means, or instructions, or any combination thereof for aligning a fourth memory die with a fifth memory die of the second multi-layer semiconductor device and adjusting, as part of the one or more alignment procedures, placement of a sixth memory die on the fourth memory die based at least in part on the alignment offset satisfying a threshold.
Aspect 6: The method, apparatus, or non-transitory computer-readable medium of any of aspects 1 through 5, where bonding the third memory die and the first memory die together establishes connections between the first memory die, the second memory die, and the third memory die.
Aspect 7: The method, apparatus, or non-transitory computer-readable medium of any of aspects 1 through 6, where bonding the third memory die and the first memory die together further includes operations, features, circuitry, logic, means, or instructions, or any combination thereof for applying a second pressure and a second temperature to the first memory die, the second memory die, and the third memory die based at least in part on aligning the third memory die with the first memory die.
Aspect 8: The method, apparatus, or non-transitory computer-readable medium of any of aspects 1 through 7, further including operations, features, circuitry, logic, means, or instructions, or any combination thereof for forming, prior to aligning the third memory die, the one or more marks in the second side of the third silicon layer.
Aspect 9: The method, apparatus, or non-transitory computer-readable medium of aspect 8, where forming the one or more marks further includes operations, features, circuitry, logic, means, or instructions, or any combination thereof for identifying a first location of a first alignment mark on the first side of the third silicon layer and forming a first alignment mark at the first location on the second side of the third silicon layer based at least in part on identifying the first location of the first alignment mark, where the one or more marks include the first alignment mark.
Aspect 10: The method, apparatus, or non-transitory computer-readable medium of aspect 9, further including operations, features, circuitry, logic, means, or instructions, or any combination thereof for forming one or more second alignment marks at additional locations on the second side of the third silicon layer based at least in part on identifying the first location of the first alignment mark, where the one or more marks include the first alignment mark and the one or more second alignment marks.
Aspect 11: The method, apparatus, or non-transitory computer-readable medium of any of aspects 8 through 10, where forming the one or more marks further includes operations, features, circuitry, logic, means, or instructions, or any combination thereof for bonding the first side of the third memory die with a carrier die; patterning the one or more marks on the second side of the third memory die based at least in part on bonding the first side of the third memory die; and debonding the third memory die from the carrier die.
Aspect 12: The method, apparatus, or non-transitory computer-readable medium of any of aspects 8 through 11, where forming the one or more marks further includes operations, features, circuitry, logic, means, or instructions, or any combination thereof for applying a layer of photoresist material on the second side of the third silicon layer; etching the photoresist material and the third silicon layer to form one or more patterns on the second side of the third silicon layer, where the one or more marks include the one or more patterns; and removing a portion of the layer of photoresist material from the second side of the third silicon layer based at least in part on etching the one or more patterns.
Aspect 13: The method, apparatus, or non-transitory computer-readable medium of aspect 12, where removing the layer of photoresist material includes operations, features, circuitry, logic, means, or instructions, or any combination thereof for performing a wet strip process to remove the layer of photoresist material from the second side of the third silicon layer.
Aspect 14: The method, apparatus, or non-transitory computer-readable medium of any of aspects 12 through 13, where etching the photoresist material and the third silicon layer to form the one or more patterns further includes operations, features, circuitry, logic, means, or instructions, or any combination thereof for performing a dry etch process on the second side of the third silicon layer.
Aspect 15: The method, apparatus, or non-transitory computer-readable medium of any of aspects 12 through 14, further including operations, features, circuitry, logic, means, or instructions, or any combination thereof for removing a polymer material formed by etching the photoresist material and the third silicon layer based at least in part on etching the one or more patterns.

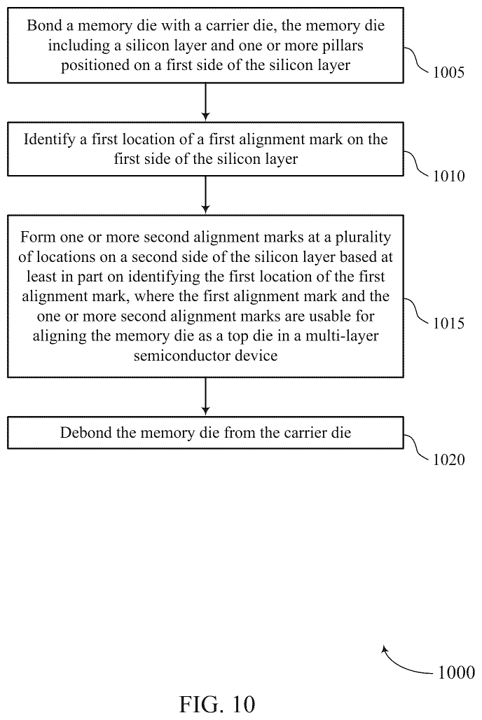

FIG. 10 shows a flowchart illustrating a method 1000 that supports top die back-side marking for memory systems in accordance with examples as disclosed herein. The operations of method 1000 may be implemented by a manufacturing system or one or more controllers or its components as described herein. For example, the operations of method 1000 may be performed by a manufacturing system or one or more controllers as described with reference to FIGS. 1 through 8. In some examples, one or more controllers may execute a set of instructions to control the functional elements of the manufacturing system to perform the described functions. Additionally, or alternatively, the manufacturing system or one or more controllers may perform aspects of the described functions using special-purpose hardware.

At 1005, the method may include bonding a memory die with a carrier die, the memory die including a silicon layer and one or more pillars positioned on a first side of the silicon layer.

At 1010, the method may include identifying a first location of a first alignment mark on the first side of the silicon layer.

At 1015, the method may include forming one or more second alignment marks at a plurality of locations on a second side of the silicon layer based at least in part on identifying the first location of the first alignment mark, where the first alignment mark and the one or more second alignment marks are usable for aligning the memory die as a top die in a multi-layer semiconductor device.

At 1020, the method may include debonding the memory die from the carrier die.

In some examples, an apparatus as described herein may perform a method or methods, such as the method 1000. The apparatus may include features, circuitry, logic, means, or instructions (e.g., a non-transitory computer-readable medium storing instructions executable by a processor), or any combination thereof for performing the following aspects of the present disclosure:
Aspect 16: A method, apparatus, or non-transitory computer-readable medium including operations, features, circuitry, logic, means, or instructions, or any combination thereof for bonding a memory die with a carrier die, the memory die including a silicon layer and one or more pillars positioned on a first side of the silicon layer; identifying a first location of a first alignment mark on the first side of the silicon layer; forming one or more second alignment marks at a plurality of locations on a second side of the silicon layer based at least in part on identifying the first location of the first alignment mark, where the first alignment mark and the one or more second alignment marks are usable for aligning the memory die as a top die in a multi-layer semiconductor device; and debonding the memory die from the carrier die.
Aspect 17: The method, apparatus, or non-transitory computer-readable medium of aspect 16, where forming the first alignment mark further includes operations, features, circuitry, logic, means, or instructions, or any combination thereof for applying a layer of photoresist material on the second side of the silicon layer; etching the photoresist material and the silicon layer to form the one or more second alignment marks on the second side of the silicon layer; and removing a portion of the layer of photoresist material from the second side of the silicon layer based at least in part on etching the one or more second alignment marks.
Aspect 18: The method, apparatus, or non-transitory computer-readable medium of aspect 17, further including operations, features, circuitry, logic, means, or instructions, or any combination thereof for removing a polymer material formed by etching the photoresist material and the silicon layer based at least in part on etching the one or more second alignment marks.

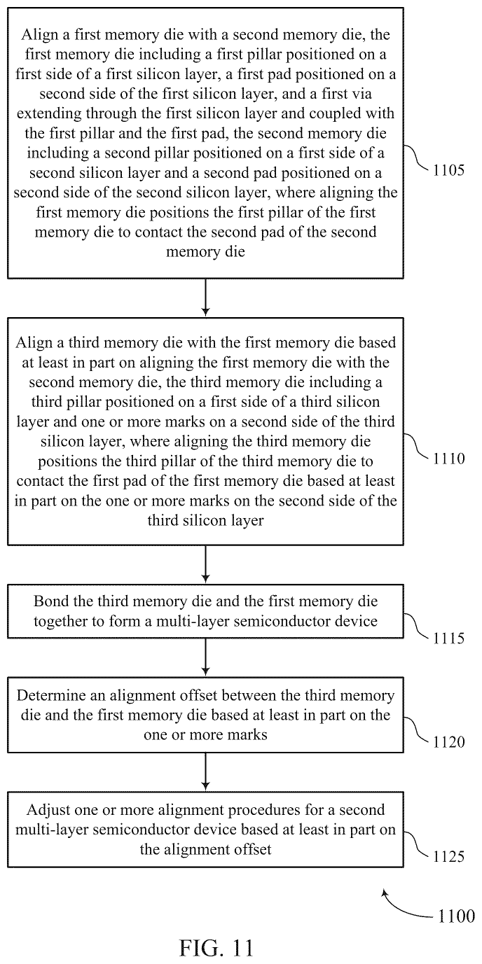

FIG. 11 shows a flowchart illustrating a method 1100 that supports top die back-side marking for memory systems in accordance with examples as disclosed herein. The operations of method 1100 may be implemented by a manufacturing system or one or more controllers or its components as described herein. For example, the operations of method 1100 may be performed by a manufacturing system or one or more controllers as described with reference to FIGS. 1 through 8. In some examples, a one or more controllers may execute a set of instructions to control the functional elements of the manufacturing system to perform the described functions. Additionally, or alternatively, the manufacturing system or one or more controllers may perform aspects of the described functions using special-purpose hardware.

At 1105, the method may include aligning a first memory die with a second memory die, the first memory die including a first pillar positioned on a first side of a first silicon layer, a first pad positioned on a second side of the first silicon layer, and a first via extending through the first silicon layer and coupled with the first pillar and the first pad, the second memory die including a second pillar positioned on a first side of a second silicon layer and a second pad positioned on a second side of the second silicon layer, where aligning the first memory die positions the first pillar of the first memory die to contact the second pad of the second memory die.

At 1110, the method may include aligning a third memory die with the first memory die based at least in part on aligning the first memory die with the second memory die, the third memory die including a third pillar positioned on a first side of a third silicon layer and one or more marks on a second side of the third silicon layer, where aligning the third memory die positions the third pillar of the third memory die to contact the first pad of the first memory die based at least in part on the one or more marks on the second side of the third silicon layer.

At 1115, the method may include bonding the third memory die and the first memory die together to form a multi-layer semiconductor device.

At 1120, the method may include determining an alignment offset between the third memory die and the first memory die based at least in part on the one or more marks.

At 1125, the method may include adjusting one or more alignment procedures for a second multi-layer semiconductor device based at least in part on the alignment offset.

In some examples, an apparatus as described herein may perform a method or methods, such as the method 1100. The apparatus may include features, circuitry, logic, means, or instructions (e.g., a non-transitory computer-readable medium storing instructions executable by a processor), or any combination thereof for performing the following aspects of the present disclosure:
Aspect 19: A method, apparatus, or non-transitory computer-readable medium including operations, features, circuitry, logic, means, or instructions, or any combination thereof for aligning a first memory die with a second memory die, the first memory die including a first pillar positioned on a first side of a first silicon layer, a first pad positioned on a second side of the first silicon layer, and a first via extending through the first silicon layer and coupled with the first pillar and the first pad, the second memory die including a second pillar positioned on a first side of a second silicon layer and a second pad positioned on a second side of the second silicon layer, where aligning the first memory die positions the first pillar of the first memory die to contact the second pad of the second memory die; aligning a third memory die with the first memory die based at least in part on aligning the first memory die with the second memory die, the third memory die including a third pillar positioned on a first side of a third silicon layer and one or more marks on a second side of the third silicon layer, where aligning the third memory die positions the third pillar of the third memory die to contact the first pad of the first memory die based at least in part on the one or more marks on the second side of the third silicon layer; bonding the third memory die and the first memory die together to form a multi-layer semiconductor device; determining an alignment offset between the third memory die and the first memory die based at least in part on the one or more marks; and adjusting one or more alignment procedures for a second multi-layer semiconductor device based at least in part on the alignment offset.
Aspect 20: The method, apparatus, or non-transitory computer-readable medium of aspect 19, further including operations, features, circuitry, logic, means, or instructions, or any combination thereof for aligning a fourth memory die with a fifth memory die of the second multi-layer semiconductor device and adjusting, as part of the one or more alignment procedures, placement of a sixth memory die on the fourth memory die based at least in part on the alignment offset satisfying a threshold.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 21: An apparatus, including: a first memory die aligned with a second memory die, the first memory die including a first pillar positioned on a first side of a first silicon layer, a first pad positioned on a second side of the first silicon layer, and a first via extending through the first silicon layer and coupled with the first pillar and the first pad, the second memory die including a second pillar positioned on a first side of a second silicon layer and a second pad positioned on a second side of the second silicon layer, where the first memory die has the first pillar of the first memory die in contact with the second pad of the second memory die; a third memory die aligned with the first memory die based at least in part on aligning the first memory die with the second memory die, the third memory die including a third pillar positioned on a first side of a third silicon layer and one or more marks on a second side of the third silicon layer, where the third memory die has the third pillar of the third memory die in contact with the first pad of the first memory die based at least in part on the one or more marks on the second side of the third silicon layer; and where the third memory die and the first memory die are bonded together to form a multi-layer semiconductor device.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
aligning a first memory die with a second memory die, the first memory die comprising a first pillar positioned on a first side of a first silicon layer, a first pad positioned on a second side of the first silicon layer, and a first via extending through the first silicon layer and coupled with the first pillar and the first pad, the second memory die comprising a second pillar positioned on a first side of a second silicon layer and a second pad positioned on a second side of the second silicon layer, wherein aligning the first memory die positions the first pillar of the first memory die to contact the second pad of the second memory die;
aligning a third memory die with the first memory die based at least in part on aligning the first memory die with the second memory die, the third memory die comprising a third pillar positioned on a first side of a third silicon layer and one or more marks on a second side of the third silicon layer, wherein aligning the third memory die positions the third pillar of the third memory die to contact the first pad of the first memory die based at least in part on the one or more marks on the second side of the third silicon layer; and
bonding the third memory die and the first memory die together to form a multi-layer semiconductor device.

2. The method of claim 1, further comprising:
bonding the first memory die and the second memory die based at least in part on aligning the first memory die with the second memory die, wherein aligning the third memory die with the first memory die is based at least in part on bonding the first memory die and the second memory die.

3. The method of claim 2, wherein:
bonding the first memory die and the second memory die together uses a first type of bonding operation comprising a first pressure and a first temperature; and
bonding the third memory die and the first memory die together uses a second type of bonding operation comprising a second pressure and a second temperature.

4. The method of claim 1, further comprising:
determining an alignment offset between the third memory die and the first memory die based at least in part on the one or more marks; and
adjusting one or more alignment procedures for a second multi-layer semiconductor device based at least in part on the alignment offset.

5. The method of claim 4, further comprising:
aligning a fourth memory die with a fifth memory die of the second multi-layer semiconductor device; and
adjusting, as part of the one or more alignment procedures, placement of a sixth memory die on the fourth memory die based at least in part on the alignment offset satisfying a threshold.

6. The method of claim 1, wherein bonding the third memory die and the first memory die together establishes connections between the first memory die, the second memory die, and the third memory die.

7. The method of claim 1, wherein bonding the third memory die and the first memory die together further comprises:
applying a second pressure and a second temperature to the first memory die, the second memory die, and the third memory die based at least in part on aligning the third memory die with the first memory die.

8. The method of claim 1, further comprising:
forming, prior to aligning the third memory die, the one or more marks in the second side of the third silicon layer.

9. The method of claim 8, wherein forming the one or more marks further comprises:
identifying a first location of a first alignment mark on the second side of the third silicon layer; and
forming a first alignment mark at the first location on the second side of the third silicon layer based at least in part on identifying the first location of the first alignment mark, wherein the one or more marks comprise the first alignment mark.

10. The method of claim 9, further comprising:
forming one or more second alignment marks at additional locations on the second side of the third silicon layer based at least in part on identifying the first location of the first alignment mark, wherein the one or more marks comprise the first alignment mark and the one or more second alignment marks.

11. The method of claim 8, wherein forming the one or more marks further comprises:
bonding the first side of the third memory die with a carrier die;
patterning the one or more marks on the second side of the third memory die based at least in part on bonding the first side of the third memory die; and
debonding the third memory die from the carrier die.

12. The method of claim 8, wherein forming the one or more marks further comprises:
applying a layer of photoresist material on the second side of the third silicon layer;
etching the photoresist material and the third silicon layer to form one or more patterns on the second side of the third silicon layer, wherein the one or more marks comprise the one or more patterns; and
removing a portion of the layer of photoresist material from the second side of the third silicon layer based at least in part on etching the one or more patterns.

13. The method of claim 12, wherein:
removing the layer of photoresist material further comprises performing a wet strip process to remove the layer of photoresist material from the second side of the third silicon layer; and
etching the photoresist material and the third silicon layer to form the one or more patterns further comprises performing a dry etch process on the second side of the third silicon layer.

14. The method of claim 12, further comprising:
removing a polymer material formed by etching the photoresist material and the third silicon layer based at least in part on etching the one or more patterns.

15. A method, comprising:
bonding a memory die with a carrier die, the memory die comprising a silicon layer and one or more pillars positioned on a first side of the silicon layer;
identifying a first location of a first alignment mark on the first side of the silicon layer;
forming one or more second alignment marks at a plurality of locations on a second side of the silicon layer based at least in part on identifying the first location of the first alignment mark, wherein the first alignment mark and the one or more second alignment marks are usable for aligning the memory die as a top die in a multi-layer semiconductor device; and
debonding the memory die from the carrier die.

16. The method of claim 15, wherein forming the first alignment mark further comprises:
applying a layer of photoresist material on the second side of the silicon layer;
etching the photoresist material and the silicon layer to form the one or more second alignment marks on the second side of the silicon layer; and
removing a portion of the layer of photoresist material from the second side of the silicon layer based at least in part on etching the one or more second alignment marks.

17. The method of claim 16, further comprising:
removing a polymer material formed by etching the photoresist material and the silicon layer based at least in part on etching the one or more second alignment marks.

18. A method, comprising:
aligning a first memory die with a second memory die, the first memory die comprising a first pillar positioned on a first side of a first silicon layer, a first pad positioned on a second side of the first silicon layer, and a first via extending through the first silicon layer and coupled with the first pillar and the first pad, the second memory die comprising a second pillar positioned on a first side of a second silicon layer and a second pad positioned on a second side of the second silicon layer, wherein aligning the first memory die positions the first pillar of the first memory die to contact the second pad of the second memory die;
aligning a third memory die with the first memory die based at least in part on aligning the first memory die with the second memory die, the third memory die comprising a third pillar positioned on a first side of a third silicon layer and one or more marks on a second side of the third silicon layer, wherein aligning the third memory die positions the third pillar of the third memory die to contact the first pad of the first memory die based at least in part on the one or more marks on the second side of the third silicon layer;
bonding the third memory die and the first memory die together to form a multi-layer semiconductor device;
determining an alignment offset between the third memory die and the first memory die based at least in part on the one or more marks; and
adjusting one or more alignment procedures for a second multi-layer semiconductor device based at least in part on the alignment offset.

19. The method of claim 18, further comprising:
aligning a fourth memory die with a fifth memory die of the second multi-layer semiconductor device; and
adjusting, as part of the one or more alignment procedures, placement of a sixth memory die on the fourth memory die based at least in part on the alignment offset satisfying a threshold.

20. An apparatus, comprising:
a first memory die aligned with a second memory die, the first memory die comprising a first pillar positioned on a first side of a first silicon layer, a first pad positioned on a second side of the first silicon layer, and a first via extending through the first silicon layer and coupled with the first pillar and the first pad, the second memory die comprising a second pillar positioned on a first side of a second silicon layer and a second pad positioned on a second side of the second silicon layer, wherein the first memory die has the first pillar of the first memory die in contact with the second pad of the second memory die; and
a third memory die aligned with the first memory die based at least in part on aligning the first memory die with the second memory die, the third memory die comprising a third pillar positioned on a first side of a third silicon layer and one or more marks on a second side of the third silicon layer, wherein the third memory die has the third pillar of the third memory die in contact with the first pad of the first memory die based at least in part on the one or more marks on the second side of the third silicon layer;
wherein the third memory die and the first memory die are bonded together to form a multi-layer semiconductor device.
